(19) United States
(12) Patent Application Publication
(10) Pub. No.: US 2013/0234732 A1
(43) Pub. Date: Sep. 12, 2013

(54) TOUCH PANEL AND METHOD FOR PRODUCING SAME

(71) Applicant: AVCT OPTICAL ELECTRONIC CO., LTD, Chung Li (TW)

(72) Inventors: JYR-DWO LEE, CHUNG LI (TW); SHIH-LIANG CHOU, CHUNG LI (TW); HSUEH- CHIH CHIANG, CHUNG LI (TW); WEN-TSUN MA, CHUNG LI (TW)

(73) Assignee: avct Optical Electronic Co., Ltd, Chung Li (TW)

(21) Appl. No.: 13/870,300

(22) Filed: Apr. 25, 2013

Related U.S. Application Data
(63) Continuation-in-part of application No. 12/847,327, filed on Jul. 30, 2010.

(30) Foreign Application Priority Data
Mar. 26, 2010 (TW) 099109075

(51) Int. Cl. H05K 13/00; H03K 17/96

(52) U.S. Cl. CPC H05K 13/0023; H03K 17/962
USPC 324/658; 228/170

(57) ABSTRACT

The invention discloses a method for producing touch panels. The method comprises providing a plastic substrate including multiple predetermined regions; forming an icon or artwork layer on the plastic substrate; forming a sensing layer on the icon or artwork layer; cutting the predetermined regions from the plastic substrate to become individual touch panels; and subjecting the touch panels to bonding, so that the peripheral wires of the respective touch panels are connected to a flexible printed circuit board.

### CROSS-REFERENCE TO RELATED APPLICATION

This application is a continuation-in-part of U.S. Ser. No. 12/847,327 filed on Jul. 30, 2010, the disclosure of which is incorporated herein by reference in its entirety.

### BACKGROUND OF THE INVENTION

1. Field of the Invention

The present invention relates to a touch panel and a method for producing the touch panel and, more particularly, to a touch panel adapted for large-scale production and a method for producing the touch panel at high productivity and low manufacture cost.

2. Description of the Prior Art

There are some common types of touch panels, namely, the resistive panels, capacitive panels, surface acoustic wave panels, optical (infrared) panels and so on. Among these, the most commonly used are the resistive panels, followed by the capacitive panels. The advantages of the capacitive touch panels are water-proofing and scratch-proofing, and they have high light transmittance and a broad range of temperature tolerance. Therefore, the panels come at a high price. With the advancement of technology, however, the capacitive touch panels are beginning to gain a share in the market of small monitors.

Typically, a conventional capacitive touch panel comprises a bottom transparent substrate, a top transparent substrate and a transparent cover lens. A top indium-tin oxide layer and a bottom indium-tin oxide layer are formed on the surfaces of the top and the bottom transparent substrates, respectively.

Afterwards, an optical clear adhesive (OCA) is applied to bind the top transparent substrate and the bottom transparent substrate, so that a layer of OCA is sandwiched between the top indium-tin oxide layer and the bottom indium-tin oxide layer facing each other. The transparent cover lens is bound to the top transparent substrate by a layer of OCA, so as to complete the assembly of the transparent capacitive touch panel. The transparent cover lens serves to protect the top and the bottom transparent substrates.

However, the conventional transparent capacitive touch panel is too thick and heavy to meet the design trend of light-weight and slimness, as the top and bottom transparent substrates and the transparent cover lens are all made of glass material. In addition, the conventional manufacturing methods can only produce a single touch panel product at a time and, thus, has limited productivity. There is a need for a method for producing touch panels at elevated productivity and reduced manufacture cost.

### SUMMARY OF THE INVENTION

An object of the invention is to provide to a touch panel adapted for large-scale production and a method for producing the touch panel at high productivity and low manufacture cost.

In order to achieve the object described above, the method according to the invention comprises the steps of : providing a plastic substrate having a top surface and a bottom surface, wherein the plastic substrate includes a plurality of predetermined regions, each of which is to be fabricated into a touch panel;
forming an icon or artwork layer on the bottom surface of the plastic substrate, wherein the icon or artwork layer comprises a plurality of icon or artwork units, each being disposed on the periphery of a corresponding one of the predetermined regions;
forming a sensing layer on the icon or artwork layer, wherein the sensing layer comprises a plurality of sensing series and a plurality of peripheral wires electrically connected to the sensing series, the sensing series being formed on an area of the predetermined regions that is not covered by the icon or artwork units, and the peripheral wires are disposed on the icon or artwork units in such a manner that they are shielded from outside by the icon or artwork units;
cutting the predetermined regions from the plastic substrate to become individual touch panels; and
subjecting the touch panels to bonding, so that the peripheral wires of the respective touch panels are connected to a flexible printed circuit board.

The invention further provides a touch panel produced by the method described above. The touch panel comprises:
a plastic substrate having a bottom surface, on which an icon or artwork unit is disposed at its periphery;
a sensing layer disposed on the bottom surface of the plastic substrate and the icon or artwork unit and comprising a plurality of sensing series and a plurality of peripheral wires electrically connected to the sensing series;
wherein the sensing series are disposed on an area of the bottom surface of the plastic substrate that is not covered by the icon or artwork unit, and the peripheral wires are disposed on the icon or artwork unit in such a manner that they are shielded from outside by the icon or artwork unit.

The invention is superior to the prior art methods in view of the following aspects:
1. The substrate used in the invention is made of plastic material and, thus, the touch panel produced by the invention is slim enough to meet the trend of light-weight and compactness for electronic products.
2. The invention allows production of multiple touch panels in a single run of operation, thereby greatly enhancing the productivity and lowering the manufacture cost.

### BRIEF DESCRIPTION OF THE DRAWINGS

The above and other objects, features and effects of the invention will become apparent with reference to the following description of the preferred embodiments taken in conjunction with the accompanying drawings, in which:

FIG. 1 is a flowchart of the method for producing touch panels according to an embodiment of the invention;

FIG. 2 is a schematic diagram of the plastic substrate used in an embodiment of the invention;

FIG. 3 is a schematic diagram showing the formation of the icon or artwork layer on the plastic substrate according to an embodiment of the invention;

FIG. 4 is a schematic diagram showing the predetermined region and the icon or artwork layer according to an embodiment of the invention;

FIG. 5 is a schematic diagram showing the formation of the sensing layer according to an embodiment of the invention;

FIG. 6 is a schematic diagram showing the finishing of the sensing layer according to an embodiment of the invention;

FIG. 7 is a schematic diagram of a touch panel obtained after the cutting according to an embodiment of the invention;

FIG. 8 is a schematic diagram of a touch panel according to an alternative embodiment of the invention; and

FIG. 9 is a schematic diagram of a touch panel according to another alternative embodiment of the invention.

### DETAILED DESCRIPTION OF THE PREFERRED EMBODIMENTS

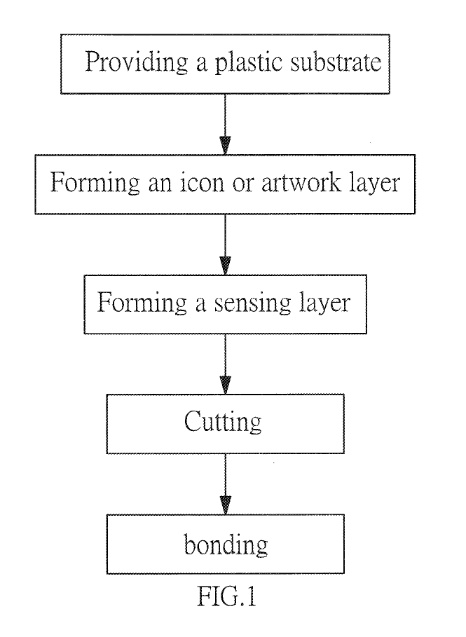

According to the flowchart shown in FIG. 1, the invented method for producing touch panels comprises the following steps.

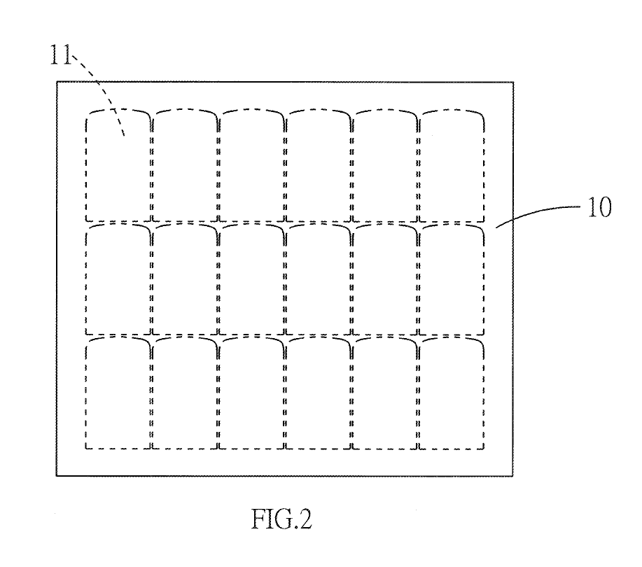

A plastic substrate 10 is provided. As shown in FIG. 2, the plastic substrate 10 includes a plurality of predetermined regions 11, optionally arranged in a matrix manner on the plastic substrate 10. Each of the predetermined regions is to be fabricated into a touch panel.

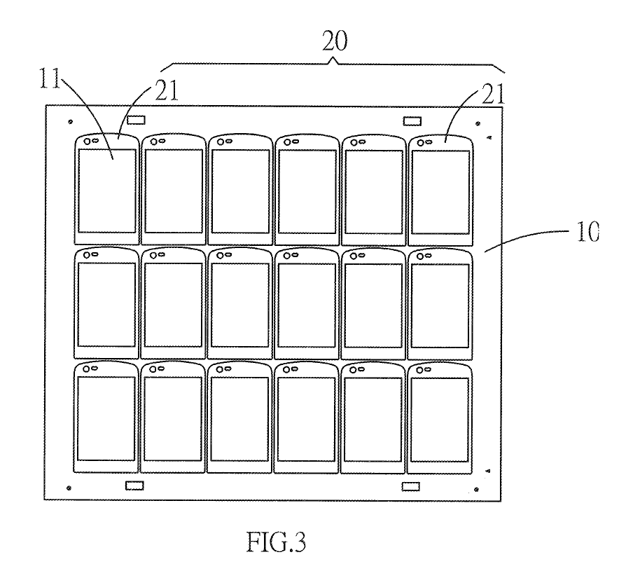

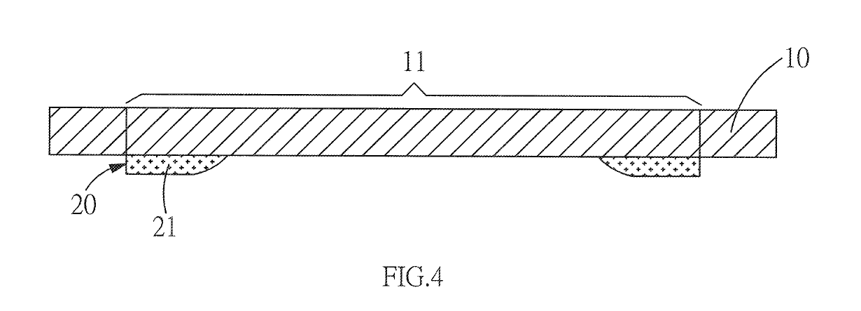

Then, an icon or artwork layer 20 is formed. As shown in FIGS. 3 and 4, the icon or artwork layer 20 is formed on the bottom surface of the plastic substrate 10 using a screen-printing, ink-jet printing or photolithographic process. The icon or artwork layer 20 comprises a plurality of icon or artwork units 21, each being disposed on the periphery of a corresponding one of the predetermined regions 11. The inner periphery of the icon or artwork unit 21 is not perpendicular to the adjacent line of the corresponding predetermined region 11, so that the formation of the subsequent structures can be complete. In the case of using a screen-printing process to form the icon or artwork units 21 whose outer surfaces meet the corresponding predetermined regions 11 at a non-perpendicular angle, the following parameters may by way of example be used in the process: an ink viscosity of 10-30 dPa·s, the screen conditioned at 50˜400 mesh tetron screen, and the tension at minimum 15 Newton force. The icon or artwork layer 20 thus formed has a film thickness of about 2˜15 μm.

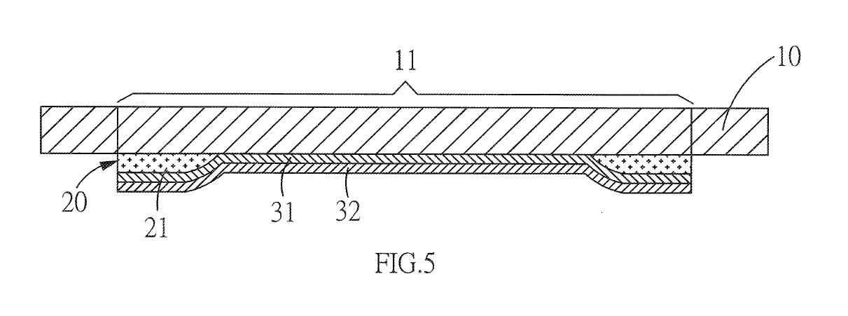

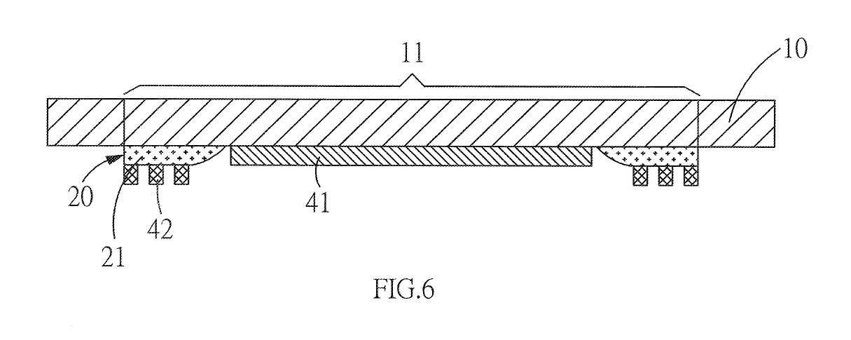

Then, a sensing layer is formed. As shown in FIG. 5, the plastic substrate 10 and the icon or artwork layer 20 are coated, in sequence, with a transparent conductive layer 31 and a metal layer 32. The transparent conductive layer 31 and the metal layer 32 are patterned (using, for example, a photolithographic process, a laser patterning process or a printing process) to form a plurality of sensing series 41 and a plurality of peripheral wires 42 electrically connected to the sensing series 41. As shown in FIG. 6, the sensing series 41 are formed on an area of the predetermined regions 11 that is not covered by the icon or artwork units 21, and the peripheral wires 42 are formed on the icon or artwork units 21 in such a manner that they are shielded from outside by the icon or artwork units 21. The transparent conductive layer 31 is made of transparent conductive material, such as ITO, with a thickness of about 10-100 nm. The transparent conductive layer 31 is preferably formed by using vacuum DC and RF magnetron sputtering deposition technique. Optionally, an alternative method, such as layer-by-layer sputtering, spray pyrolysis, pulsed laser deposition, arc discharge ion plating, reactive evaporation, ion beam sputtering, or chemical vapor deposition (CVD) etc. can be used. Considering the temperature tolerance of the plastic substrate 10 used in the method, the coating of the transparent conductive layer 31 and the metal layer 32 is preferably carried out at a temperature of less than 100° C.

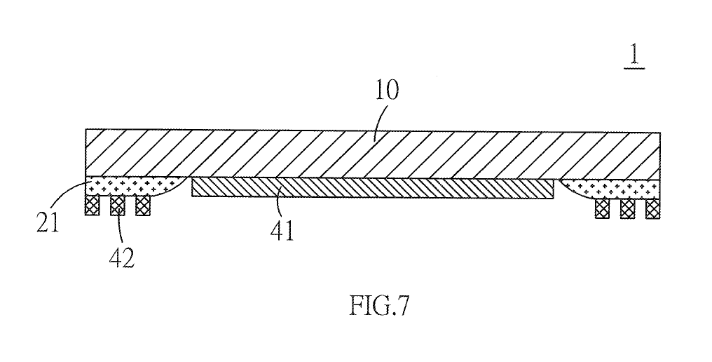

Afterwards, the respective predetermined regions 11 are cut from the plastic substrate 10 to become individual touch panels 1, as shown in FIG. 7. The cutting step can be carried out on a CNC cutting machine, a contour cutting machine, or a laser cutting machine. Considering the mechanical strength of the plastic substrate 10 used in the method, the plastic substrate 10 is preferably subjected to air-cooled dry cutting, whereby it is cut by a synthetic diamond-coated tungsten carbide rotary blade operated at a rotary speed of 10,000˜30,000 rpm, preferably about 25,000 rpm, and a forward speed of 1000˜5000 mm/min, preferably about 3000 mm/min.

After cutting, the obtained touch panels are subjected to a bonding step, in which the peripheral wires 42 of the respective touch panels 1 are connected to a flexible printed circuit board (not shown), thereby producing finished touch panel products. It should be noted that the cutting step and the bonding step shown in FIG. 1 can be interchanged. That is to say, the cutting step may be carried out either prior to or subsequent to the bonding step. Considering the temperature tolerance of the plastic substrate 10 used in the method, the bonding is preferably carried out at a relatively low temperature, more preferably less than 120° C., and a pressure of 1˜2 bar, more preferably about 1.5 bar, for a time period of 10˜40 seconds, more preferably about 25 seconds.

The touch panel produced according to the invention comprises a plastic substrate. According to the embodiment shown in FIG. 7, the touch panel comprises a plastic substrate 10 having a bottom surface, on which an icon or artwork unit 21 is disposed at its periphery. A sensing layer is disposed on the bottom surface of the plastic substrate 10 and the icon or artwork unit 21 and comprises a plurality of sensing series 41 and a plurality of peripheral wires 42 electrically connected to the sensing series 41. The sensing series 41 are disposed on an area of the bottom surface of the plastic substrate 10 that is not covered by the icon or artwork unit 21, and the peripheral wires 42 are disposed on the icon or artwork unit 21 in such a manner that they are shielded from outside by the icon or artwork unit 21. In addition, the icon or artwork unit 21 has an inner periphery that is not perpendicular to the adjacent line of the plastic substrate 10, so that the cladding of the subsequent structures can be complete.

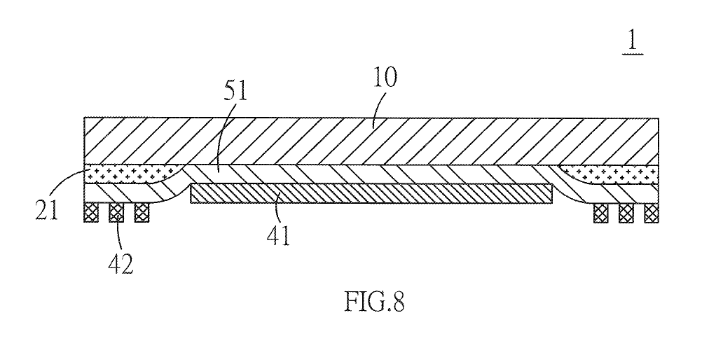

In addition, an optical film may be formed before and/or after the formation of the sensing layer, so that the sensing layer is coated on one or both of its surfaces with the optical film. According to an alternative embodiment shown in FIG. 8, the bottom surface of the plastic substrate 10 is further provided with a first optical film 51, on which the sensing layer is mounted. The first optical film 51 is disposed on the icon or artwork unit and an area of the bottom surface of the plastic substrate 10 that is not covered by the icon or artwork unit 21. The first optical film 51 serves to minimize the adverse effect of the etched pattern of the sensing layer on the user's visual perception. The first optical film 51 may be formed to have a thickness of less than 200 nm by a sputtering, spraying or coating process.

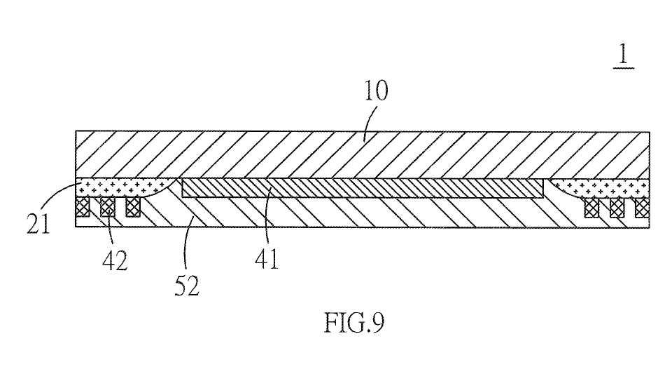

It is apparent to those skilled in the art that the sensing layer may be additionally coated with a second optical film. According to the embodiment shown in FIG. 9, the sensing layer is further coated with a second optical film 52, such as an anti-glare coating or an anti-reflection coating, as a means to enhance the overall transparency.

While the invention has been described with reference to the preferred embodiments above, it should be recognized that the preferred embodiments are given for the purpose of illustration only and are not intended to limit the scope of the present invention and that various modifications and changes, which will be apparent to those skilled in the relevant art, may be made without departing from the spirit of the invention and the scope thereof as defined in the appended claims.

What is claimed is:

1. A method for producing touch panels, comprising the steps of
providing a plastic substrate having a top surface and a bottom surface, wherein the plastic substrate includes a plurality of predetermined regions, each of which is to be fabricated into a touch panel;
forming an icon or artwork layer on the bottom surface of the plastic substrate, wherein the icon or artwork layer comprises a plurality of icon or artwork units, each being disposed on the periphery of a corresponding one of the predetermined regions;
forming a sensing layer on the icon or artwork layer, wherein the sensing layer comprises a plurality of sensing series and a plurality of peripheral wires electrically connected to the sensing series, the sensing series being formed on an area of the predetermined regions that is not covered by the icon or artwork units, and the peripheral wires being disposed on the icon or artwork units in such a manner that they are shielded from outside by the icon or artwork units;
cutting the predetermined regions from the plastic substrate to become individual touch panels; and
subjecting the touch panels to bonding, so that the peripheral wires of the respective touch panels are connected to a flexible printed circuit board.

2. The method for producing touch panels according to claim 1, wherein the bonding of the touch panels is carried out subsequent to the forming of the sensing layer and prior to the cutting step.

3. The method for producing touch panels according to claim 1, wherein the icon or artwork layer is formed using a screen-printing, ink-jet printing or photolithographic process.

4. The method for producing touch panels according to claim 1, wherein the icon or artwork units each has an inner periphery that meets the corresponding predetermined region at a non-perpendicular angle.

5. The method for producing touch panels according to claim 1, wherein the forming of the sensing layer comprises sequentially coating a transparent conductive layer and a metal layer on the plastic substrate and the icon or artwork layer, and patterning the transparent conductive layer and the metal layer to form the sensing series and the peripheral wires electrically connected to the sensing series.

6. The method for producing touch panels according to claim 5, wherein the forming of the sensing layer is carried out using sputtering deposition technique at a temperature of less than 100° C.

7. The method for producing touch panels according to claim 1, wherein the cutting step is performed using air-cooled dry cutting.

8. The method for producing touch panels according to claim 7, wherein the air-cooled dry cutting is carried out using a synthetic diamond-coated tungsten carbide rotary blade.

9. The method for producing touch panels according to claim 1, wherein the bonding of the touch panels is carried out at a temperature of less than 120° C.

10. The method for producing touch panels according to claim 1, further comprising, before and/or after the forming of the sensing layer, a step of forming an optical film, so that the sensing layer is coated on one or both of its surfaces with the optical film.

11. A touch panel produced by the method according to claim 1, comprising:
a plastic substrate having a bottom surface, on which an icon or artwork unit is disposed at its periphery;
a sensing layer disposed on the bottom surface of the plastic substrate and the icon or artwork unit and comprising a plurality of sensing series and a plurality of peripheral wires electrically connected to the sensing series;
wherein the sensing series are disposed on an area of the bottom surface of the plastic substrate that is not covered by the icon or artwork unit, and the peripheral wires are disposed on the icon or artwork unit in such a manner that they are shielded from outside by the icon or artwork unit.

12. The touch panel according to claim 11, further comprising a first optical film sandwiched between the bottom surface of the plastic substrate and the sensing layer, wherein the first optical film is disposed on the icon or artwork unit and an area of the bottom surface of the plastic substrate that is not covered by the icon or artwork unit.

13. The touch panel according to claim 12, further comprising a second optical film disposed on the sensing layer.

14. The touch panel according to claim 11, further comprising a second optical film disposed on the sensing layer.

15. The touch panel according to claim 11, wherein the icon or artwork unit has an inner periphery that meets the plastic substrate at a non-perpendicular angle.

16. A touch panel produced by the method according to claim 2, comprising:
a plastic substrate having a bottom surface, on which an icon or artwork unit is disposed at its periphery;
a sensing layer disposed on the bottom surface of the plastic substrate and the icon or artwork unit and comprising a plurality of sensing series and a plurality of peripheral wires electrically connected to the sensing series;
wherein the sensing series are disposed on an area of the bottom surface of the plastic substrate 10 that is not covered by the icon or artwork unit, and the peripheral wires are disposed on the icon or artwork unit in such a manner that they are shielded from outside by the icon or artwork unit.

17. The touch panel according to claim 16, further comprising a first optical film sandwiched between the bottom surface of the plastic substrate and the sensing layer, wherein the first optical film is disposed on the icon or artwork unit and an area of the bottom surface of the plastic substrate that is not covered by the icon or artwork unit.

18. The touch panel according to claim 17, further comprising a second optical film disposed on the sensing layer.

19. The touch panel according to claim 16, further comprising a second optical film disposed on the sensing layer.

20. The touch panel according to claim 16, wherein the icon or artwork unit has an inner periphery that meets the plastic substrate at a non-perpendicular angle.
